(19) United States
(12) Patent Application Publication
(10) Pub. No.: US 2026/0267215 A1
(43) Pub. Date: Sep. 10, 2026

(54) TWO LEVEL-SET BASED APPROACH FOR TRITONE ATTENUATED PHASE SHIFT MASKS (attPSM) AND RELATED APPLICATIONS

(71) Applicant: KLA Corporation, Milpitas, CA (US)

(72) Inventors: Ying He, San Jose, CA (US); Changqing Hu, Sunnyvale, CA (US); Vikram Tolani, San Jose, CA (US); Lu Yu, Shanghai (CN); Zeyu Lei, Shanghai (CN)

(21) Appl. No.: 19/204,451

(22) Filed: May 9, 2025

Related U.S. Application Data
(60) Provisional application No. 63/766,387, filed on Mar. 4, 2025.

(51) Int. Cl. G03F 1/32; G03F 1/84

(52) U.S. Cl. CPC G03F 1/32; G03F 1/84

(57) ABSTRACT

Methods and systems for determining information for a photomask are provided. One method includes determining tone of a photomask as a function of position on the photomask by applying predefined rules to reference data for the photomask when multiple level sets of the photomask overlap. The photomask has three or more tones, and the multiple level sets include three or more definitions for the three or more tones, respectively. The method also includes determining information for the photomask from the determined tone as the function of the position on the photomask. The embodiments described herein provide particular advantages as a two level-set based approach for lithography modeling of tritone attenuated phase shift masks (attPSMs) and related applications of automatic defect classification (ADC) and lithography plane review (LPR) in photomask inspection.

### BACKGROUND OF THE INVENTION

### 1. Field of the Invention

This invention generally relates to methods and systems for determining information for a photomask. Certain embodiments relate to methods and systems configured for a two level-set based approach for lithography modeling of tritone attenuated phase shift (attPSM) masks and related applications including automatic defect classification (ADC) and lithography plane review (LPR) in photomask inspection.

### 2. Description of the Related Art

The following description and examples are not admitted to be prior art by virtue of their inclusion in this section.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a photomask to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

An attenuated phase shift mask (attPSM), also commonly referred to as a “half-tone mask,” is a type of photomask used in photolithography to enhance the resolution of semiconductor devices. It uses a patterned layer of molybdenum silicide (MoSi) that causes a phase shift of the transmitted light by 180°.

The original halftone phase shift mask (PSM) shows significant improvement on the depth of focus (DOF) for hole pattern printing on wafers. However, there is also need for caution when using this technique on other patterns, such as line and space patterns or patterns surrounded by bright fields, due to potential sub-peak effects that could deteriorate these patterns when printed on wafers. A tritone PSM mask is a specific new structure of attPSM in which a chrome (Cr) film is partially placed on the half tone surface, further enhancing the resolution by reducing diffraction effects, so the advantages of these masks can be extended to line patterns.

However, the intricate patterns and multiple phase shifting regions in tritone attPSM make inspection more complex. This complexity can lead to higher false detection rates during reticle inspection. Inspection tools need careful calibration to accurately differentiate three different types of geometries: clear quartz features, partially transparent embedded phase shifter geometries, and opaque chrome features. This calibration is essential to ensure sensitivity and reduce false detections. Residual Cr on the mask edges can complicate the inspection process. Innovative techniques, such as Cr shrinking, are being developed to address this issue and improve inspectability.

Automatic defect classification (ADC) offers a complete and systematic approach to defect disposition and classification. ADC automates the defect classification process, reducing the reliance on manual inspection, which is costly and error prone. ADC achieves relatively high throughput, classifying over 250 defects per minute with a matching rate of over 90% compared to human classifications. ADC allows for higher inspection sensitivity and success rates, particularly for masks with aggressive optical proximity correction (OPC) features.

Some currently used methods introduce a technique called lithography plane review (LPR) to address the challenges of inspection and dispositioning defects in sub-32 nm mode mask patterns. LPR uses inverse lithography technology (ILT) to reconstruct defective masks from inspection images and perform simulated aerial image dispositioning. This method allows for high-resolution inspection while maintaining accuracy and throughput, predicting actual aerial imaging measurements with substantially high precision and processing over 250 defects per minute.

Despite ongoing advancements in mask inspection tools, the complexity and new challenges introduced by tritone attPSM continue to result in increased false and nuisance defect detections. Traditionally, masks have contained only two materials, chrome and glass (COG) or MoSi and glass (attPSM)), and inspection processes have been optimized for these binary mask presentations. However, the presence of three materials with different transmission types complicates inspection, requiring three distinct light levels to differentiate between them and detect defects. This complexity renders currently used computer-aided software like ADC and LPR inadequate for tritone attPSM mask inspection if binary mask-based lithography modeling is still used. Therefore, it is crucial to redesign the workflow and enhance lithography modeling with improved mask representation.

Accordingly, it would be advantageous to develop methods and/or systems for determining information for a photomask that do not have one or more of the disadvantages described above.

### SUMMARY OF THE INVENTION

The following description of various embodiments is not to be construed in any way as limiting the subject matter of the appended claims.

One embodiment relates to a system configured for determining information for a photomask. The system includes a computer system configured for determining tone of a photomask as a function of position on the photomask by applying predefined rules to reference data for the photomask when multiple level sets of the photomask overlap. The photomask has three or more tones. The multiple level sets include three or more definitions for the three or more tones, respectively. The computer system is also configured for determining information for the photomask from the determined tone as the function of the position on the photomask. The system may be further configured as described herein.

Another embodiment relates to a computer-implemented method for determining information for a photomask. The method includes the determining tone and determining information steps described above, which are performed by a computer system. The method may be performed as described further herein. The method may include any other step(s) of any other method(s) described herein. The method may be performed by any of the systems described herein.

An additional embodiment relates to a non-transitory computer-readable medium storing program instructions executable on a computer system for performing a computer-implemented method for determining information for a photomask. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Other objects and advantages of the invention will become apparent upon reading the following detailed description and upon reference to the accompanying drawings in which:

FIG. 1 is a block diagram illustrating an embodiment of a system configured for determining information for a photomask;

FIG. 2 is a flow chart illustrating an example of a general flow of automatic defect classification (ADC) and multiple steps that may be included in an image preparation step;

FIG. 3 is a flow chart illustrating the general flow of the ADC shown in FIG. 2 with an example of multiple steps that may be included in a defect classification step;

FIG. 4 is a flow chart illustrating one example of simulation-based patterning lookup on design for a mask;

FIG. 5 is a flow chart illustrating one example of an incorrect design loading performed for a tritone attenuated phase shift mask (attPSM) and incorrect converting the loaded design to a binary attPSM representation;

FIG. 6 is a flow chart illustrating one embodiment of a correct design loading performed for a tritone attPSM and correct converting the loaded design to a tritone attPSM representation;

FIG. 7 is a schematic diagram illustrating an example of ADC defect topology using a wrong (binary) lookup for a tritone attPSM vs. ADC defect topology using a correct (tritone) lookup for the tritone attPSM;

FIG. 8 is a schematic diagram illustrating an example of an original single level-set binary mask representation;

FIG. 9 is a schematic diagram illustrating an embodiment of an initial setup using two level set functions for a tritone mask presentation;

FIG. 10 is a flow chart illustrating one embodiment of a new ADC flow that supports a two level-set based tritone mask model;

FIG. 11 is a schematic diagram illustrating one embodiment of a method for lithography printability reviewer (LPR);

FIG. 12 is a flow chart illustrating one embodiment of a method for LPR;

FIG. 13 is a schematic diagram illustrating different results that may be generated for an edge defect on a chrome layer when a tritone mask is incorrectly treated as a binary mask vs. correctly treated as a tritone mask; and

FIG. 14 is a block diagram illustrating one embodiment of a non-transitory computer-readable medium storing program instructions executable on a computer system for performing one or more of the computer-implemented methods described herein.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

The terms “design,” “design data,” and “design information” as used interchangeably herein generally refer to the physical design (layout) of an IC or other semiconductor device and data derived from the physical design through complex simulation or simple geometric and Boolean operations. The design may include any other design data or design data proxies described in commonly owned U.S. Pat. No. 7,570,796 issued on Aug. 4, 2009 to Zafar et al. and U.S. Pat. No. 7,676,077 issued on Mar. 9, 2010 to Kulkarni et al., both of which are incorporated by reference as if fully set forth herein. In addition, the design data can be standard cell library data, integrated layout data, design data for one or more layers, derivatives of the design data, and full or partial chip design data. Furthermore, the “design,” “design data,” and “design information” described herein refers to information and data that is generated by semiconductor device designers in a design process and is therefore available for use in the embodiments described herein well in advance of printing of the design on any physical specimens such as reticles and wafers.

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

The embodiments described herein generally relate to systems and methods for determining information for a photomask (also referred to herein as a “mask” and a “reticle”). In one embodiment, the photomask is configured as a tri-tone attenuated phase-shift (attPSM) mask, and the multiple level sets include two level sets. The embodiments may generate and use a numerical contour representation of a photomask with three (or more) tones, such as a tritone attPSM. The embodiments employ a two-level set approach to represent the tritone mask and utilize predefined rules to determine the tone when the two level-sets overlap. Additionally, the embodiments provide a workflow for integrating the two level-set based mask representation and approach into numerical lithography modeling of tritone attPSM masks, enhancing the accuracy of applications such as automatic defect classification (ADC) and lithography plane review (LPR), also referred to herein as a lithographic printability reviewer, in reticle inspections. The two level-set based approaches described herein provide a key differentiator from other currently used methods and systems. These non-trivial innovative approaches are described further herein.

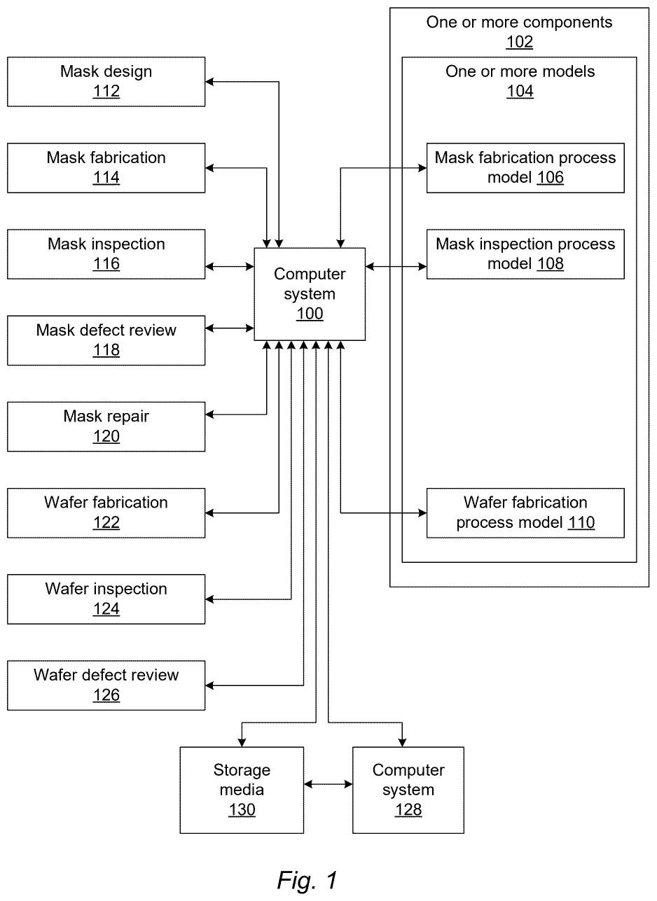

One embodiment of a system configured for determining information for a mask is shown in FIG. 1. The system includes computer system 100 and possibly one or more components 102 executable by the computer system. This computer system (as well as other computer systems described herein) may also be referred to herein as computer subsystem(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer system, the different computer systems may be coupled to each other such that images, data, information, instructions, etc. can be sent between the computer systems. For example, computer system 100 may be coupled to computer system 128 by any suitable transmission media, which may include any suitable wired and/or wireless transmission media known in the art. Two or more of such computer systems may also be effectively coupled by a shared computer-readable storage medium, e.g., storage media 130.

Computer system 128 may not be coupled to any of the tools described herein. In this manner, one of the computer systems may be a stand alone type computer system, which may be coupled to the other computer system shown in FIG. 1. A stand alone type computer system may therefore be configured to perform one or more steps described herein.

The one or more components may include one or more models 104 such as a fabrication process model of a fabrication process performed to fabricate a mask (i.e., mask fabrication process model 106) and/or an inspection process model of an inspection process performed to inspect the mask (i.e., mask inspection process model 108). The one or more models are configured for generating at least one of a simulated representation of a fabricated mask and a simulated inspection image of the fabricated mask based on a design for the mask. In this manner, the embodiments may model the layout using the expected writer/process and/or inspection process model. For example, mask design process and/or tool 112 may be configured to generate a design for the mask in any suitable manner known in the art. In one such example, mask design process and/or tool 112 may be any suitable commercially available electronic design automation (EDA) tool known in the art configured to generate any of the design data described herein. The design for the mask may be acquired by computer system 100 from the mask design process and/or tool and the tone of the photomask may be determined as described further herein and then input to one or more of mask fabrication process model 106 and mask inspection process model 108. The computer system may be configured to input the design for the mask, the tone for the photomask determined as described herein, and any other information for the mask into the one or more models in any suitable manner. The model(s) may then generate one or more outputs as described further herein.

The input to the one or more models may also include any relevant information about the various process(es) and tool(s) that they simulate in addition to the design and other information for the mask. For example, the input to mask fabrication process model 106 may include information for mask fabrication process and/or tool 114, and the input to mask inspection process model 108 may include information for mask inspection process and/or tool 116. The information for mask fabrication process and/or tool 114 and/or mask inspection process and/or tool 116 may be provided to or acquired by computer system 100 in any suitable manner known in the art, e.g., directly from the tool(s) themselves, from a storage medium in which the information is stored, etc.

The mask fabrication and mask inspection process and/or tool may include any suitable such processes or tools known in the art. In addition, both mask fabrication and mask inspection may be performed with one or more processes and/or one or more tools. Any relevant information from any of these processes and/or tools may be provided to computer system for input to the one or more models.

The simulated representation of the fabricated mask that is generated by mask fabrication process model 106 may include a two-dimensional (e.g., top down) representation of the fabricated mask. However, the mask fabrication process model may be configured to generate a three-dimensional representation of the fabricated mask in some cases, e.g., depending on the model itself.

In general, the simulated inspection image of the fabricated mask generated by the mask inspection process model will be substantially similar in appearance to an actual image of the fabricated mask that would be generated by a given inspection tool with a given set of inspection tool and/or process parameters. The simulated inspection image may also be a simulated raw detector image, i.e., an image that would be generated by a detector of an inspection system with a given set of inspection process parameters and before that image is subject to any image processing. In some cases, such as when multiple modes are used for mask inspection, the mask inspection process model may generate multiple simulated inspection images that would be generated for the same area of the mask during a single mask inspection process, e.g., with different illumination and/or collection/detection parameters of the inspection tool. To determine information for the mask as described herein, the computer system may apply any suitable image processing to the simulated inspection images that would normally be performed during, for example, defect detection. The image processing may include any such image processing performed in any suitable manner, and the defect detection may be performed as described further herein.

The fabrication process model and the inspection process model may include a physical or empirical model of the fabrication process and the inspection process, respectively. For example, the models may be a physical or empirical model of the noise or variation of the mask fabrication process (including the e-beam mask writer) and/or the mask inspection process (including a mask inspection tool) that will be used to inspect the plate.

In this manner, the embodiments may be configured for generating a simulated representation of a physical version of the mask from information for the mask and/or generating a simulated inspection image of the physical version of the mask generated by an inspection system, from the information for the mask or from the simulated representation of the physical version of the mask. In other words, the embodiments may generate the simulated representation of the fabricated mask by simulating the physical mask having the design formed thereon and/or generate the simulated inspection image by simulating how that mask would appear in images generated by the inspection process.

Generating the simulated representation of the fabricated mask may include nearfield modeling, and generating the simulated inspection image of the physical version of the mask may include partial coherent illumination modeling. In this manner, the fabrication process model may be or include nearfield modeling, which is to capture the mask pattern information, and the inspection process model may be or include partial coherent illumination modeling. Such modeling may be performed as described in U.S. Pat. No. 9,478,019 to Sezginer et al. issued Oct. 25, 2016, which is incorporated by reference as if fully set forth herein. The embodiments described herein may be further configured as described in this patent. The modeling may also or alternatively be performed in any other suitable manner known in the art.

In one embodiment, the fabrication process model is configured for generating different simulated representations of the fabricated mask for different values of one or more parameters of the fabrication process, e.g., via a model of the noise or variation of the mask fabrication process (including the e-beam mask writer). The noise or variation may be any possible (intentional or not) variation in one or more parameters of the mask fabrication process(es) and/or tool(s). In other words, the mask fabrication parameter values that are input to the mask fabrication process model may include parameter values that could be intentionally selected and used to fabricate the mask and/or parameter values that could be unintentionally used to fabricate the mask due to drift, variation, marginalities, etc. in the mask fabrication process(es) and/or tool(s). The resulting simulated representations of the fabricated mask may be used as described further herein.

A mask layout and/or information determined from the mask layout such as tone as a function of position determined as described herein may be input to a mask process variations simulation with mask process variations information. The mask process variations information may vary depending on the mask fabrication process and tool(s) and how much or how little each of the mask fabrication process parameters may vary. Some non-limiting examples of mask process variations information include a writing tool model (e.g., e-beam dose, shape, misplacement variation), a resist process model (e.g., photo resist bake, development, etch variation), line edge roughness (LER), line width roughness (LWR), stochastic model (e.g., empirical parameters from a process for variation). The output of the simulation may then be layout with mask process variations.

In another embodiment, the inspection process model is configured for generating different simulated inspection images of the fabricated mask for different values of one or more parameters of the inspection process. For example, the inputs to an inspection image simulation may include the mask layout, the tone as a function of position on the photomask determined according to embodiments described herein, etc. and inspection conditions. Some non-limiting examples of possible inspection conditions that may be input to the inspection image simulation include mask stack parameters (i.e., information for the materials from which the mask is formed), inspection tool optics (e.g., information such as the type of inspection tool, its make and model, parameters of the light or e-beam source, parameters of the detectors, etc.), illumination/polarization information (e.g., information about the parameters of the illumination of the mask including, but not limited to, illumination polarization, aperture type, pupil configuration, speckle, flare, aberration variation, etc.), Maxwell Acc (i.e., an electromatic field around mask predicted with Maxwell equation with rigorous approach), and defocus values (e.g., +/−30 mm defocus).

The mask layout, the determined tone as a function of position, etc. may then be input to the inspection image simulation with various inspection conditions, and the inspection image simulation may generate a simulated inspection image of the mask for each of the different inspection conditions. For example, the inspection image simulation may generate a simulated inspection image for nominal focus, a simulated inspection image for negative focus error, and a simulated inspection image for positive focus error. In a similar manner, simulated inspection images may be generated for any other of the inspection parameter values described above (e.g., different simulated images for different types of inspection tools, different apertures, different pupil configurations, etc.). In addition, the embodiments described herein may be configured for generating any number of simulated inspection images, which may be limited by the user for practical considerations and/or by the number of different inspection parameter values that are possible and/or of interest).

The inspection image simulation may model the noise or variation of the mask inspection process (including the inspection tool). The noise or variation may be possible (intentional or not) variation in one or more parameters of the mask inspection process(es) and/or tool(s). In other words, the mask inspection parameter values that are input to the mask inspection process model may include parameter values that could be intentionally selected and used to inspect the mask and/or parameter values that could be unintentionally used to inspect the mask due to drift, variation, marginalities, etc. in the mask inspection process(es) and/or tool(s). The resulting simulated mask inspection images may be used as described further herein.

As described above, a mask process variations simulation may be configured for simulating different representations of the mask with mask process variations using the mask layout, the tone determined as described herein, etc. and mask fabrication process parameter values as input. The different representations with mask process variations may then be input to an inspection image simulation along with information for different inspection process and/or tool parameter values. The different inspection process and/or tool parameter values may include, but are not limited to, an inspection tool model, which may include parameter values for the mask film stack (e.g., tone) such as that described herein, inspection optics including the information described above, any applicable equations like Kirchhoff, e.g., for approximation by transmission and phase, Maxwell rigorous simulation described above, CompactM3D, e.g., approximation of EM for speed, etc., and other inspection process and/or tool information like focus, speckle, flare, aberration variations, etc. The output of the inspection image simulation may then include a simulation of an inspection image with variation and a simulation of an inspection image without variation. The embodiments described herein may be configured for generating as many simulated inspection images as practical and/or selected.

The one or more models may also include a wafer fabrication process model of a lithography process performed to print the fabricated mask on a wafer (i.e., wafer fabrication process model 110 shown in FIG. 1) and configured for generating a simulated representation of a wafer printed with the fabricated mask. For example, the input to wafer fabrication process model 110 may include information for wafer fabrication process and/or tool 122. The information for wafer fabrication process and/or tool 122 may be provided to or acquired by computer system 100 in any suitable manner known in the art, e.g., directly from the tool itself, from a storage medium in which the information is stored, etc., and then input to wafer fabrication process model 110 as described herein.

The wafer fabrication process model may be or include mask near-field simulation, which can use either Kirchoff approximation, rigorous finite difference time domain (FDTD) solver, rigorous coupled wave analysis (RCWA), or a compact approximation model such as a Defect Printability Simulator (DPS) mask model (examples of which are described in “Compensation methods using a new model for buried defects in extreme ultraviolet lithography masks,” by Clifford et al., Photomask Technology 2010, Proceedings of SPIE Vol. 7823, 78230V, Sep. 24, 2010, 10 pages, which is incorporated by reference as if fully set forth herein), optics, and resist exposure and development models, which may include any suitable such models known in the art. The embodiments described herein may be configured as described in the above-referenced paper. Generating the simulated representation of the wafer may also be performed as described in U.S. Pat. No. 9,002,497 issued Apr. 7, 2015 to Marella et al. and U.S. Pat. No. 9,478,019 issued Oct. 25, 2016 to Sezginer et al., which are incorporated by reference as if fully set forth herein. The embodiments described herein may be further configured as described in these patents.

The wafer fabrication process model may also be configured for simulating aerial images for the simulated representation of the fabricated mask and generating the simulated representation of the wafer based on the simulated aerial images. For example, a scanner model may be applied to a simulated representation of the fabricated mask with associated scanner exposure conditions to generate a corresponding aerial image. The scanner model may be applied to the simulated representation of the fabricated mask as described further herein. In this manner, the computer system may run printability simulations with scanner optical conditions. The Aerial Image Analyzer (AIA) may then be run to compute printability of all features within a simulated aerial image. For example, aerial images simulated for different scanner conditions may be input to an AIA that may generate simulated images showing how the scanner conditions would affect the features of the mask in the aerial image projected on a wafer during a lithography process. Examples of the AIA that may be used in the embodiments described herein are described in “Printability and actinic AIMS review of programmed mask blank defects,” by Verduijn et al., SPIE Proceedings Vol. 10143, Extreme Ultraviolet (EUV) Lithography VIII, 101430K, Mar. 24, 2017, 13 pages, which is incorporated by reference as if fully set forth herein. The embodiments described herein may be further configured as described in this publication.

The simulated representation of the wafer that is generated by wafer fabrication process model 110 may include a two-dimensional representation of the fabricated wafer or a three-dimensional representation of the fabricated wafer in some cases, e.g., depending on the model itself.

The computer system may be configured for selecting sites on the mask for defect review based on the results generated by embodiments described herein. For example, the computer system may select sites and/or one or more other parameters of mask defect review 118 shown in FIG. 1 based on the results of the ADC and/or LPR described herein. In this manner, the computer system may be configured for mask scanning electron microscope (SEM) review site selection (and printability assessment). In one such example, one or more of the defects that are classified by ADC may be selected for mask defect review to ensure that these defects are classified correctly and/or to determine additional information about the defects.

In a similar manner, the computer system may be configured for determining one or more parameters of any other process or tool performed on or with the mask or a different mask. In just one such example, the computer system may be configured for determining one or more parameters of a mask metrology process and/or tool (not shown) in the same manner described herein with respect to mask inspection. In another such example, the computer system may be configured for determining one or more parameters of mask repair process and/or tool 120 based on the results generated by the embodiments described herein. For example, the computer system may be configured to select one or more of the defects classified by ADC as locations at which repair is performed.

The computer system may also be configured for selecting sites on a wafer printed with the mask for wafer defect detection performed during a wafer inspection process based on results generated as described herein. For example, the computer system may be configured for selecting sites and/or one or more other parameters for wafer inspection process and/or tool 124. The sites and/or one or more other parameters of wafer inspection may be selected in the same manner as described above with respect to mask inspection. In addition, the computer system may be configured for selecting sites and/or one or more other parameters for other processes performed on the wafer printed with the fabricated mask. In one such example, the computer system may be configured for selecting one or more parameters for wafer defect review process and/or tool 126 in the same manner described above with respect to mask defect review.

The wafer defect detection may be performed to detect defects on the mask. For example, the wafer inspection performed by process and/or tool 124 may be a PrintCheck type inspection process in which a wafer is specifically printed and inspected to determine if defects on a mask print or otherwise produce defects in the pattern printed on the wafer. In this manner, a “PrintCheck” or “print check” is performed to identify defects on the mask based on the wafer inspection results. The computer system may therefore be configured for wafer PrintCheck site selection and/or hotspot management. In one such example, the computer system may select patterns or locations on the mask at which one or more defects were detected for print check type inspection. In this manner, these patterns and/or locations can be examined further to determine whether or not they have an impact on the printed wafer.

The computer system is configured for determining tone of a photomask as a function of position on the photomask by applying predefined rules to reference data for the photomask when multiple level sets of the photomask overlap. The photomask has three or more tones, and the multiple level sets include three or more definitions for the three or more tones, respectively. In this manner, the embodiments described herein provide a method for determining the tone of a tritone photomask by applying predefined rules when two level sets overlap. For applications such as ADC and LPR, the embodiments enhance the capability of lithography simulators to simulate tritone attPSM using a two level-set based approach. The embodiments described herein are different in important ways from currently used one level-set based simulation models, which are primarily designed for binary masks. In addition, although the embodiments may be described herein with respect to tritone attPSM, the embodiments may be used for any type of mask having three or more tones.

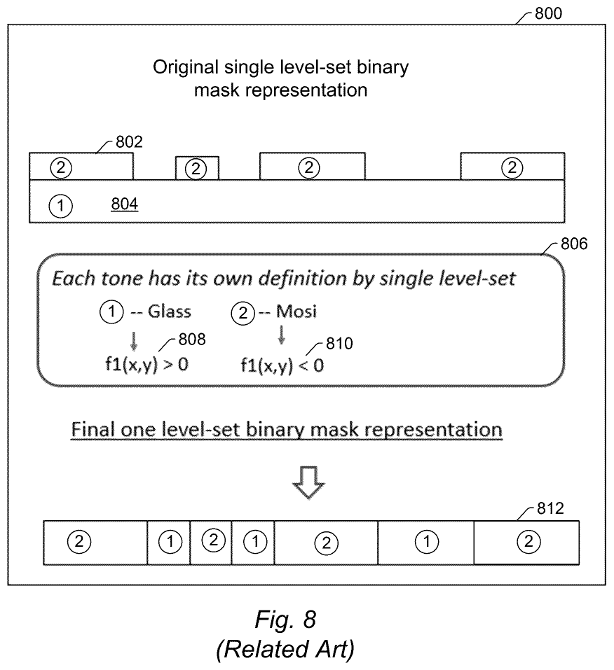

FIG. 8 illustrates an example of a currently used, original single level-set binary mask representation 800. In other words, FIG. 8 shows an initial setup using one level set functions for a binary mask presentation. The binary mask in this case includes molybdenum silicide (MoSi or Mosi) phase shifting features 802 (also indicated in FIG. 8 by the number 2 within a circle) formed on glass substrate 804 (also indicated in FIG. 8 by the number 1 within a circle). Definitions 806 (or level set representation rules) may be used to generate the final one level-set binary mask representation. Each tone has its own definition by single level-set. In particular, definition 808 for glass is f1(x,y)>0, and definition 810 for MoSi is f1(x,y)<0. These definitions may be applied to the reference data for the mask such as that described herein to generate final one level-set binary mask representation 812.

As shown by comparison of the binary mask to the binary mask representation, the binary mask representation accurately represents the binary mask. In other words, in areas of the mask that include MoSi, the corresponding areas in the binary mask representation are correctly assigned a MoSi designation. In addition, in areas of the mask that do not include MoSi, the corresponding areas in the binary mask representation are correctly assigned a glass designation.

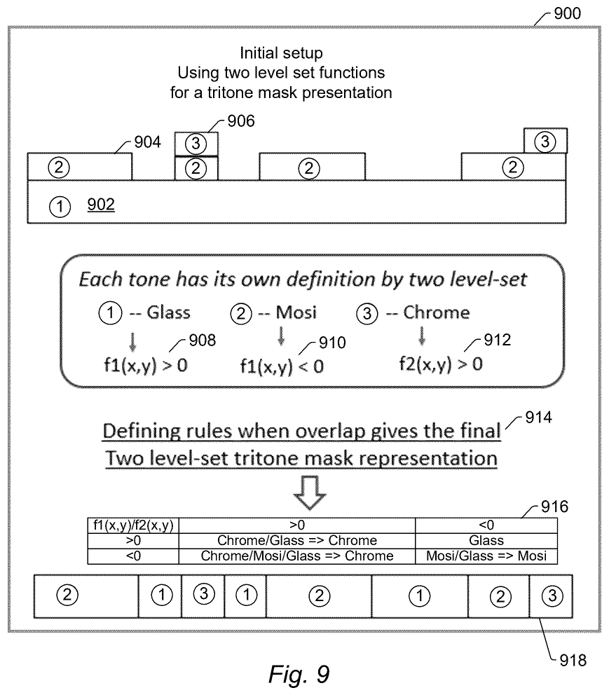

FIG. 9 illustrates an embodiment of initial setup 900 using two level set functions for a tritone mask presentation. A tritone attPSM in this case includes MoSi phase shifting features 904 (also indicated in FIG. 9 by the number 2 within a circle) and chrome features 906 (also indicated in FIG. 9 by the number 3 within a circle) formed on glass substrate 902 (also indicated in FIG. 9 by the number 1 within a circle). As shown in FIG. 9, the chrome features may be formed on top of the MoSi features. Definitions (and level set representation rules) may be used to generate the final two-level set mask representation. Each tone has its own definition by two level-set. In this case, definition 908 for glass is f1(x,y)>0, and definition 910 for MoSi is f1(x,y)<0. Definition 912 for chrome is f2(x,y)>0. Step 914 includes defining rules for when different materials on the mask overlap to give the final two level-set tritone mask representation, which may be output as table 916 that includes the defining rules.

These rules may be applied to the reference data for the mask such as that described herein to generate final two-level set tritone attPSM mask representation 918. As shown by comparison of the tritone attPSM mask to the final two-level set tritone mask representation, the two-level set tritone mask representation accurately represents the tritone attPSM mask. In particular, in areas of the mask that include MoSi but not chrome, the corresponding areas in the tritone mask representation are correctly assigned a MoSi designation. In areas of the mask that include chrome (on top of MoSi as shown in FIG. 9), the corresponding areas in the tritone mask representation are correctly assigned a chrome designation. In areas of the mask that do not include MoSi or chrome, the corresponding areas in the tritone mask representation are correctly assigned a glass designation.

The reference data that is used to determine the tone of the photomask as described herein may include any of the design data described herein or a reference mask, which may be generated in any suitable manner known in the art. The tone of the photomask may be determined as the function of position in any suitable manner, e.g., tone as a function of reticle coordinates, tone as a function of area on the photomask, etc. In addition, although the tone is shown in FIG. 9 as being determined as a function of x or y, the tone may also be determined as a function of both x and y on the photomask, particularly since the tone that is determined as described herein may be used for applications that may be performed at positions on the photomask that are different in both x and y.

In one embodiment, determining the tone includes identifying boundaries of the multiple level sets as the function of the position on the photomask thereby generating a numerical contour representation of the photomask, and applying the predefined rules includes determining zero contours of the predefined rules from the numerical contour representation. For example, the embodiments described herein provide a numerical contour representation method for a tritone photomask such as a tritone attPSM using a two-level set approach. In the two-level set representation of a tritone mask, the computer system may identify the interfaces or boundaries of the three-tone materials, which are the zero contours of the level set functions. The positive or negative values of the level set functions away from the zero contours determine the actual material, as illustrated in FIG. 9 via a matching table.

In another embodiment, the computer system is configured for storing the determined tone as the function of the position on the photomask as a two-level set-based representation of the photomask. The determined tone may be stored in any suitable manner described further herein and in any suitable computer-readable media as described herein. In this manner, the determined tone and any other results generated by the embodiments described herein may be stored so that they can be used for one or more other functions, steps, processes, etc., some of which are described herein. In other words, although some applications for which the determined tone is particularly useful are described in detail herein, the determined tone and any other information generated by the embodiments described herein may be used in any suitable manner to determine, alter, setup, etc. any of the processes/tools shown in FIG. 1. In addition, the determined tone and any other information generated by the embodiments described herein may be input to one or more of the processes/tools shown in FIG. 1.

The computer system is also configured for determining information for the photomask from the determined tone as the function of the position on the photomask. Determining the information for the photomask may include performing one or more of the functions described herein such as ADC and LPR. For example, the embodiments described herein provide a workflow for integrating a two-level set-based mask representation into lithography modeling of tritone masks to enhance accuracy of tritone mask design lookup and topology markup in ADC. The embodiments also provide a workflow for integrating a two-level set-based mask representation and their movement during optimization into tritone mask pattern recovery and demonstrate significantly more valuable advantages in tritone LPR.

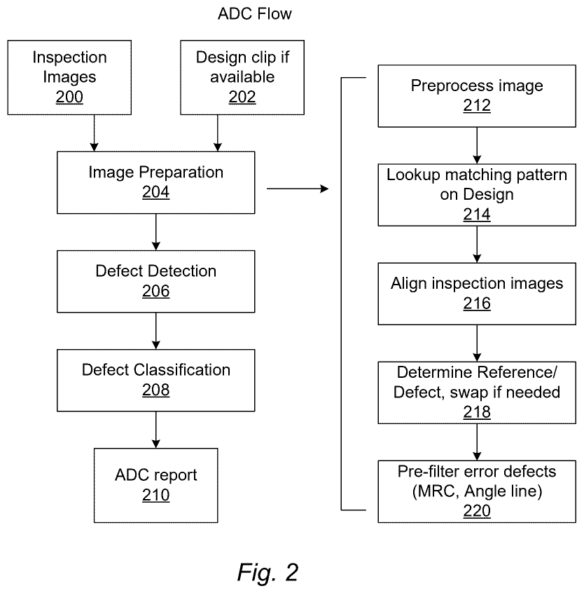

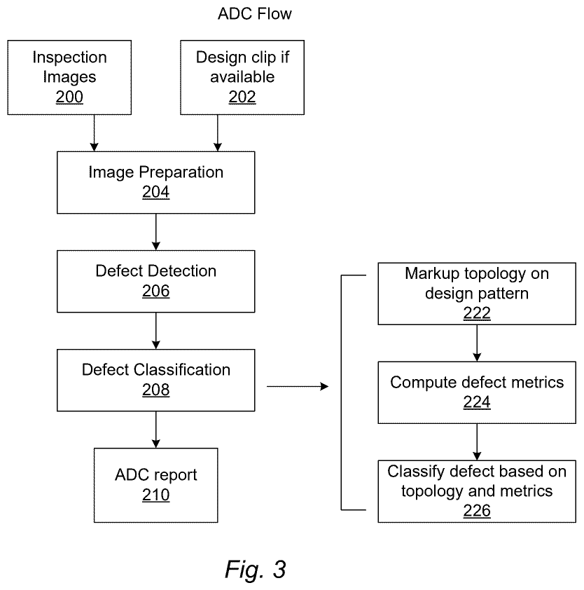

FIGS. 2 and 3 illustrate some steps that may be performed for ADC, which may be modified as described further herein. These figures show a general flow of ADC for die-to-die (D2D)/multi-die (MD) mask inspections with design (e.g., GDS). The ADC engine flow may begin with inputs including inspection images 200 and design clip if available 202. The inspection images may be acquired from an inspection tool and may include test and reference images from both transmitted and reflected light settings. The design clip if available may include any of the design data or information described further herein. The general ADC flow has 3 major phases or steps: image preparation 204, defect detection 206, and defect classification 208, which generates final ADC report 210. Defect classification 208 bins the defect sites detected in defect detection 206 into a “type” and “status.” Type defines the category into which the defect will be binned, and status provides the pass or fail decision provided by the tool.

FIG. 2 also shows some of the steps that may be performed for image preparation 204. These steps include preprocessing the image in step 212, lookup matching pattern on design in step 214, aligning inspection images in step 216, determining reference/defect images, swapping if needed in step 218, and pre-filtering error defects (e.g., mask rule check (MRC), angle line) in step 220. FIG. 3 shows some of the steps that may be performed for defect classification 208. These steps include markup topology on design pattern in step 222, compute defect metrics in step 224, and classify defects based on topology and metrics in step 226. Each of these steps may be performed in any suitable manner known in the art.

The accuracy of two of the steps, lookup matching pattern on design in step 214 and markup topology on design pattern in step 222 will severely suffer if the methods and systems designed for binary masks are used for tritone attPSM. In particular, as described further herein, simulations are crucial for pattern matching on design. In addition, design based topology markup can only be successful if the design lookup step is successful.

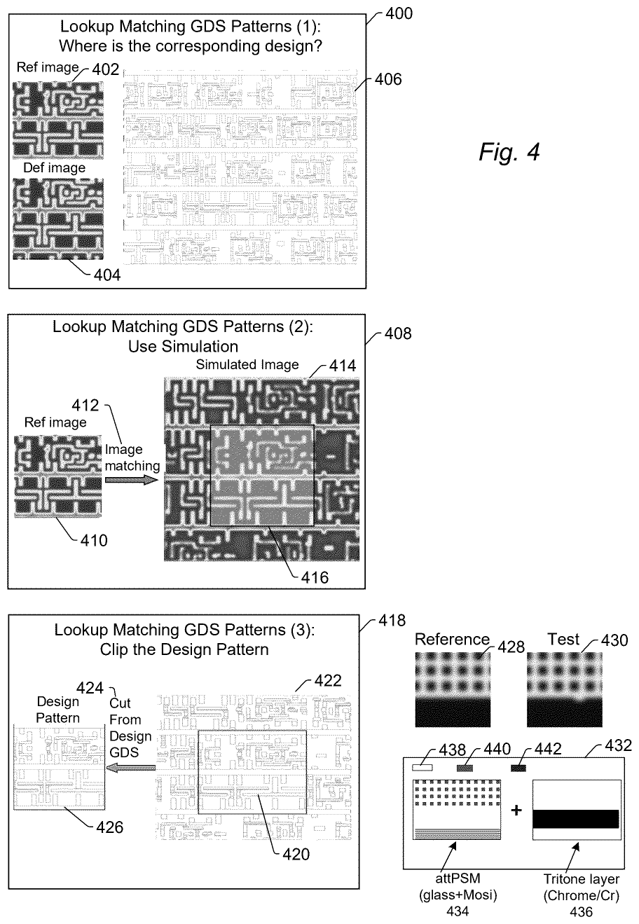

The challenges of simulation-based patterning lookup on design (e.g., GDS) are shown in more detail in FIG. 4. Currently used ADC software is mainly designed for inspection on a binary mask. The ADC application assumes a binary design is provided and performs a simulation-based patterning lookup as shown in FIG. 4. In lookup matching GDS patterns step 400, the method tries to find the corresponding design in design data 406 for reference (Ref) image 402 and defect (Def) image 404. As can be seen in step 400, the design data can be significantly different than both the reference image and the defect image, which can cause this step to fail by either returning no matching pattern, returning the wrong matching pattern, etc.

If lookup matching GDS patterns step 408 is instead performed with simulated image 414, the simulated image looks much more similar to reference image 410 than design data 406. Simulated image 414 may be generated by simulating a reference image that would be generated by a reticle inspection tool for a reticle on which design data 406 is fabricated. Generating the simulated image may be performed as described herein. Therefore, in image matching step 412, portion 416 of the simulated image may be successfully matched to reference image 410.

Once the portion of the simulated image that matches the reference image has been found in step 408, lookup matching GDS patterns step 418 may include finding portion 420 of design data 422 that corresponds to portion 416 of simulated image 414 and cutting that portion from the design GDS in step 424 to generate design pattern 426 that matches the reference image. For example, since the simulated image used in step 408 may be generated from the design data, the existing spatial correlation between the simulated image and the design data can be used to find the portion of the design data corresponding to the portion of the simulated image that matches the reference image. That matching portion of the design data may then be clipped, cut, or extracted from the entire design data in any suitable manner known in the art.

ADC flows mainly designed for binary masks may, therefore, include three major steps: loading and converting design data clips (to binary images), generating simulated images, and topology markup. The question then becomes, what if the inspection images are from a tritone attPSM mask instead of a binary mask. These challenges can be seen by comparing inspection images, including reference image 428 and test image 430, to mask layout 432 (larger GDS clips for lookup), in which different shadings are used to indicate glass 438, MoSi 440, and chrome 442. In particular, the mask layout may be defined with multiple layouts including one for the attPSM (glass and MoSi) layout 434 and one for the tritone layer (chrome/Cr) layout 436. As can be seen in FIG. 4, reference image 428 and test image 430 do not look particularly similar to either of mask layouts 434 and 436.

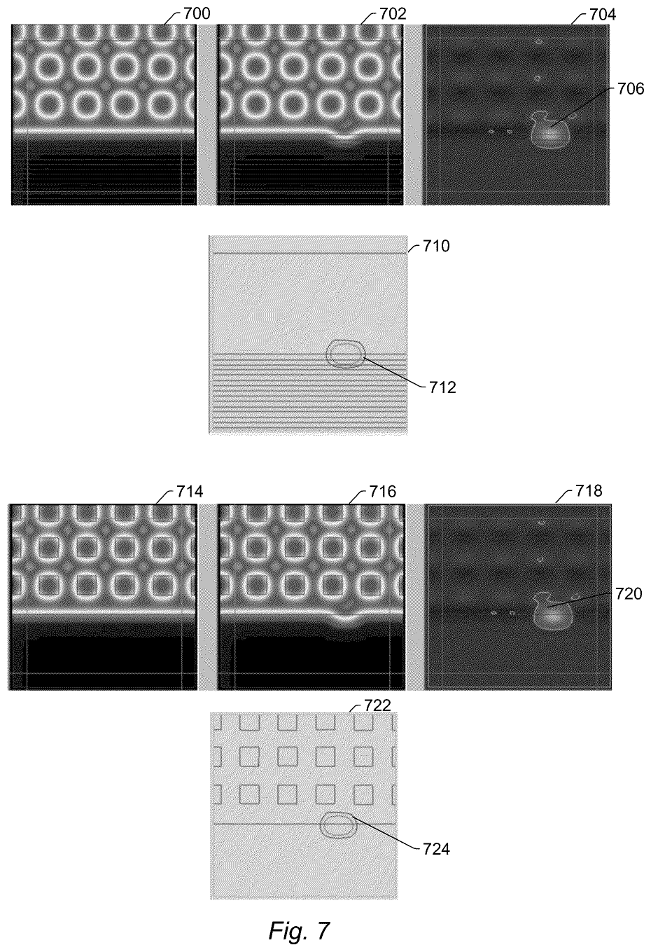

These challenges for ADC are further illustrated in FIG. 7. For example, as shown in FIG. 7, the inspection images generated for defect 706 on a mask include reference transmitted inspection image 700, test transmitted inspection image 702, and difference transmitted inspection image 704, in which defect 706 was detected. The ADC defect topology for this tritone mask may be generated based on reference mask contour image 710 using the wrong (binary) lookup, in which a defect image contour 712 is included. In inspection images 700, 702, and 704, the reference mask contour 712 is overlaid for better comparison with topology information. Since there are obvious differences between the reference, test, and difference images generated by inspection vs. simulation, defect 706 in difference inspection image 704 may be incorrectly classified as a defect on or near dense line Sub-Resolution Assist Features (SRAFs) based on the topology from the design information included in reference mask contour image 710.

In contrast, as further shown in FIG. 7, for reference transmitted inspection image 714, test transmitted inspection image 716, and difference transmitted inspection image 718, in which defect 720 was detected, ADC defect topology generated based on reference mask contour image 722 using the correct (tritone) lookup will produce the correct defect classification for defect 724. In these inspection images 714, 716, and 718, the reference mask contour 722 is overlaid for better comparison with topology information, in which the same defect image contour 724 as defect contour 712 is included. Since the reference, test, and difference images generated by inspection can now be compared to the correct topology information, the defect can now be correctly classified by ADC as a defect along the edge of the chrome layer.

Applying currently used ADC flows to tritone attPSM masks has, therefore, a number of issues and challenges. For example, there is a flow design issue. More specifically, the need to load and convert multiple GDS files representing three tones exceeds the capability of systems and methods designed for binary masks that include only two tones. There may also be numerical simulation issues. For example, using a single level set to represent a tritone mask for lithography simulation is inadequate. In addition, the currently used methods and systems may generate incorrect topology markups for tritone attPSM masks. In particular, errors may arise from incorrect pattern lookup and/or lack of additional knowledge about the location/coverage of the third tone material.

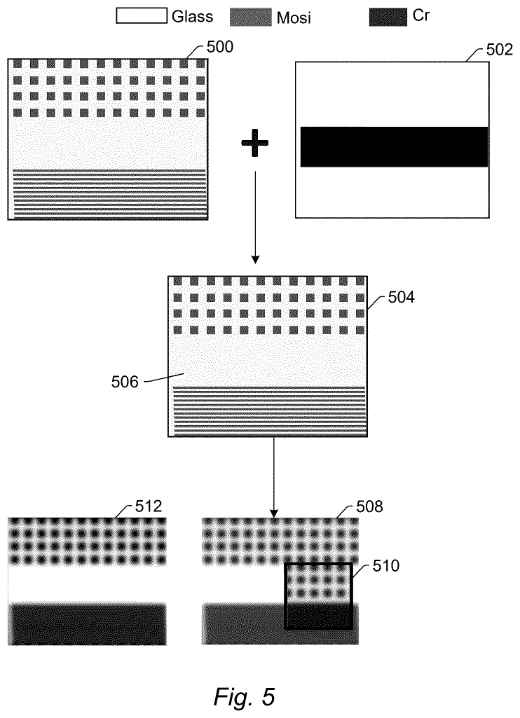

FIG. 5 shows why binary mask approaches used in ADC are insufficient for tritone attPSM masks. In particular, FIG. 5 shows an ADC flow mainly designed for binary masks and what may happen if it is directly applied for tritone masks without any modifications. In the loading and converting design clip (to binary) step, the tritone layer may be merged to the main optical proximity correction (OPC) layer, so chrome may be erroneously converted to glass or MoSi. In the generating simulated image step, the tritone layer material property incorrectly identified as glass or MoSi will likely produce an incorrect simulated image. In the pattern lookup step, the possible lookup status may include success, fail, or fake success. In the topology markup step, no reliable topology markup from design may be generated or an incorrect topology markup may be output.

In this manner, incorrect design data loading and converting to binary attPSM will have adverse consequences for other steps in the ADC process. The incorrect design data loading and converting to binary attPSM are further shown in FIG. 5. In particular, as shown by merged attPSM (glass and Mosi) binary image 504 generated from attPSM (glass+MoSi) binary image 500 and tritone layer (chrome/Cr) binary image 502, the chrome in binary image 502 has been erroneously converted to glass 506. If this image is used to generate simulated inspection image 512, then overlay 508 of inspection image 510 to the simulated image via faked lookup will have a relatively high matching score of 0.86 even though the inspection image has been incorrectly matched to the simulated image.

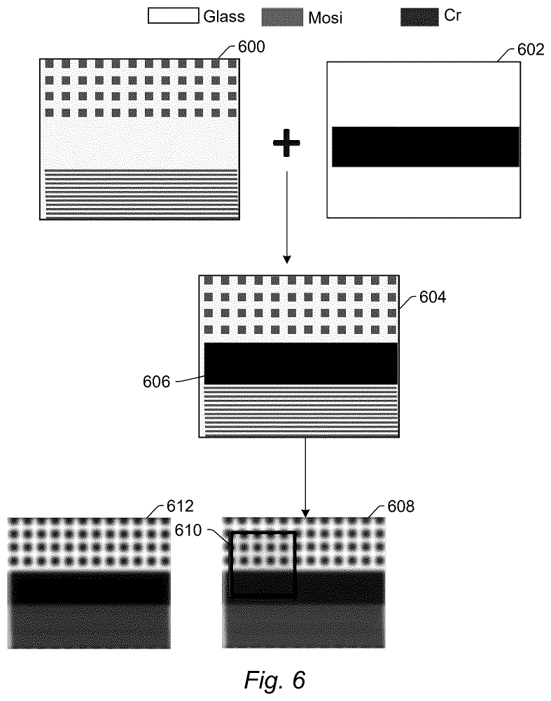

FIG. 6 illustrates correctly identifying a tritone chrome layer and using a two-level set based tritone attPSM mask representation for lithography simulation. With more accurate lithography simulation, the overall lookup results will significantly improve. In early ADC, the lithography simulator uses only one level set to represent binary masks and is therefore incapable of performing lithography simulation for tritone masks. In contrast, the embodiments described herein provide new support of ADC on tritone attPSM masks with appropriate improvements to the currently used systems and methods (e.g., engine, GUI, etc.) and using two level sets to represent tritone masks. To support tritone attPSM mask types in an ADC flow, glass is correctly identified as clear quartz features, MoSi is correctly identified as partially transparent embedded phase shifter geometries, and Cr is correctly identified as opaque chrome features, which were previously incorrectly identified either as quartz or phase shifter such as MoSi.

The embodiments described herein may also be modified to provide special handling for negative tone masks on the tritone layer. For example, the embodiments described herein may be modified for a tritone mask with negative tone by adding options to flip or not flip the tone of the third tone layer (e.g., the chrome layer) while also flipping the other two tones of the main glass/MoSi layers. In addition, the new support of ADC on tritone attPSM masks provides easy extendibility to tritone LPR due to the two level set mask representation.

More specifically, in the expected correct design data loading and converting to tritone attPSM, as shown by merged attPSM (glass and Mosi) binary image 604 generated from attPSM (glass+MoSi) binary image 600 and tritone layer (chrome/Cr) binary image 602, the chrome in binary image 602 has been correctly converted to chrome 606. If this image is used to generate simulated inspection image 612, then overlay 608 of inspection image 610 to the simulated image via successful lookup will have a relatively high matching score of 0.99 because the inspection image has been correctly matched to the simulated image.

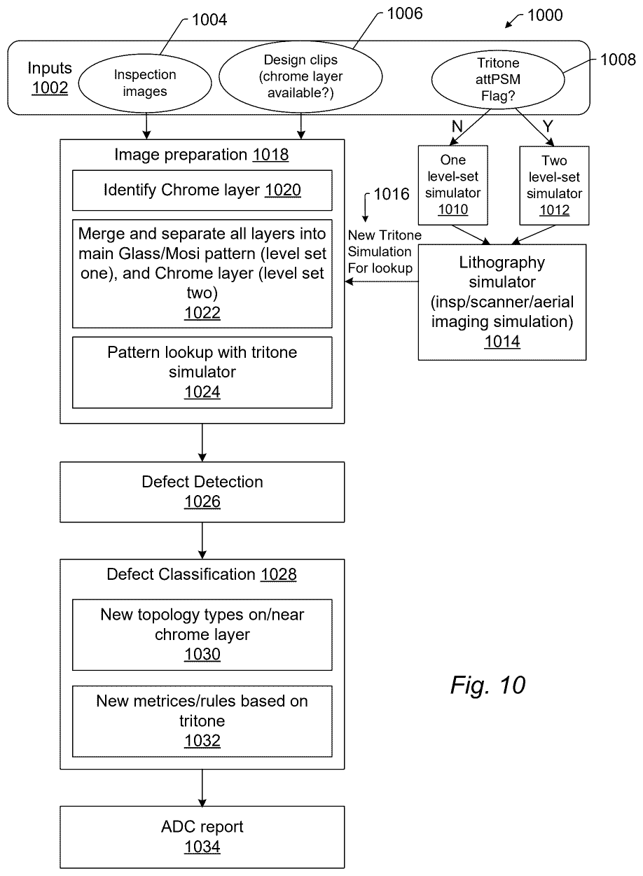

FIG. 10 illustrates an embodiment of steps performed for ADC 1000 that includes some important differences from the currently used methods for ADC. In particular, the new ADC flow shown in FIG. 10 supports a two level-set based tritone mask model. As shown in FIG. 10, inputs 1002 for ADC 1000 may include, but are not limited to, inspection images 1004, which may include any of the inspection images described herein, design clips 1006, which may include any of the design data or information described herein, and possibly tritone attPSM flag 1008. As shown in FIG. 10, design clips may be input possibly with a designation that a chrome layer is available and/or the computer system may determine if a chrome layer is available from the design clips. In addition, the inputs may include a tritone attPSM flag for the mask for which the ADC is being performed, or the computer system may determine if a tritone attPSM flag is included in the inputs or if one should be applied.

When the inputs indicate and/or the computer system determines that the mask does not have a tritone attPSM flag, then the computer system may use one level-set simulator 1010 to generate a one level-set binary mask representation of the non-tritone attPSM mask. The one level-set simulator may be configured to generate the one level-set binary mask representation as shown in FIG. 8. When the inputs indicate and/or the computer system determines that the mask does have a tritone attPSM flag, then the computer system may use two level-set simulator 1012 to generate a two level-set tritone mask representation of the tritone attPSM mask, which may be performed as shown in FIG. 9.

In one embodiment, determining the information includes lithography modeling of the photomask based on the determined tone as the function of the position on the photomask. For example, as shown in FIG. 10, either the one level-set binary mask representation generated by one level-set simulator 1010 or the two level-set tritone mask representation generated by two level-set simulator 1012 may be input to lithography simulator 1014. Lithography simulator 1014 may be configured to perform one or more simulations based on the one-or two-level set mask representation, such as inspection imaging simulations, scanner simulations, aerial imaging simulations, etc., each of which may be performed as described further herein.

In one such embodiment, determining the information also includes identifying design data for the photomask as the function of the position on the photomask based on results of the lithography modeling. In the case of a two level-set mask representation input to lithography simulator 1014, new tritone simulation for lookup 1016 may be generated and input to image preparation phase 1018 of ADC. In addition to the new tritone simulation for lookup, inspection images 1004 and design clips 1006 may be input to the image preparation phase 1018 of ADC.

Image preparation phase 1018 may include all of the image preparation steps shown in FIG. 2. However, the lookup matching pattern on design step 214 shown in FIG. 2 may be replaced with the new steps shown in FIG. 10. The new steps for looking up matching patterns on design shown in FIG. 10 include identifying chrome layer step 1020, step 1022 in which merging and separating all layers into main glass/MoSi pattern (level set one) and chrome layer (level set two) is performed, and pattern lookup with tritone simulator step 1024. Each of these steps may be performed as described further herein. In this manner, the design data for the photomask as the function of the position on the photomask may be identified based on results of the lithography modeling.

The ADC flow shown in FIG. 10 also includes defect detection step 1026, which may be performed in any suitable manner known in the art. For example, a reference image for the mask may be subtracted from a test image for the mask, thereby generating a difference image. A threshold may then be applied to the difference image, and any portion(s) of the difference image having a value above the threshold may be identified as a defect or defect candidate. Of course, this is perhaps the simplest method for defect detection, and defect detection step 1026 may be performed in any suitable manner using any suitable defect detection method and/or algorithm. The results of the defect detection step may be input to defect classification phase 1028.

Like the image preparation phase, the defect classification phase may include the same steps as defect classification 208 shown in FIG. 3. However, in the new ADC flow, markup topology on design pattern step 222 shown in FIG. 3 may be replaced with one or more new steps. In another such embodiment, determining the information includes identifying topology of the photomask as the function of the position on the photomask based on results of the lithography modeling. For example, as shown in FIG. 10, one of the new steps that may replace step 222 shown in FIG. 3 includes identifying new topology types on/near a chrome layer, as shown in step 1030. This step may be performed to identify topology of the photomask as the function of the position on the photomask based on results of the lithography modeling performed by lithography simulator 1014 and input to image preparation phase 1018. The topology of the mask determined in step 1030 may be determined in any suitable manner and may have any suitable form or format known in the art.

Another of the new steps may include identifying new metrices/rules based on tritone, as shown in step 1032. The new metrices/rules determined based on tritone may be defect metrices and/or defect classification rules. For example, a new defect metric may be the location of a defect relative to an edge of a tritone layer. A new defect classification rule may include classifying any defect that is spaced from the edge of a tritone layer by less than a predetermined amount as a tritone edge defect. These new metrices and/or rules may have any suitable form or format known in the art. In other words, the metrices and/or rules may have the same form and/or format as other metrices and/or rules currently used for ADC.

In an additional embodiment, determining the information includes performing ADC of one or more defects detected on the photomask based on at least the identified topology and/or the new metrices and/or rules. For example, in defect classification phase 1028, defect classification may be performed for defects detected in defect detection step 1026 based on at least the new topology types on/near the chrome layer identified in step 1030. In addition, the defect classification may be performed by determining the new metrices from the topology information and/or applying new rules to the topology information and/or the new metrices. The flow shown in FIG. 10 may also include generating ADC report 1034, which may include the defect classifications assigned to the defects in phase 1028, possibly in addition to any of the inputs to the ADC flow and any other information generated by the ADC flow shown in FIG. 10.

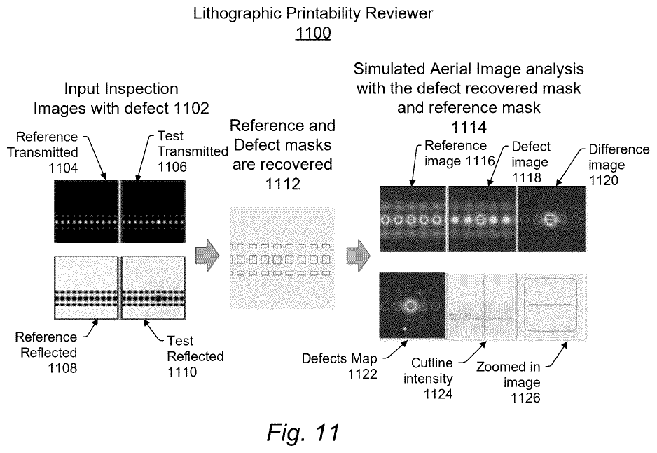

LPR methods and systems aim to recover a defect mask from inspection images (e.g., transmitted and reflected) followed by a printability check (e.g., critical dimension error (CDE), edge placement error (EPE), transmission, etc.) via aerial imaging simulation on the original reference mask and recovered defect mask. FIG. 11 shows a general LPR flow and highlights that the lithography model accuracy is crucial for final performance of defected mask recovery. Therefore, LPR also faces a challenge when a single level set is used to represent a tritone attPSM for lithography simulation.

More specifically, in LPR 1100, input inspection images with defect 1102 may include reference transmitted image 1104, test transmitted image 1106, reference reflected image 1108, and test reflected image 1110. From the input images, reference and defect masks are recovered in step 1112. LPR 1100 also includes simulated aerial image analysis with the defect recovered mask and reference mask 1114. This step may generate reference image 1116, defect image 1118, difference image 1120, defects map 1122, cutline intensity plot 1124, and zoomed in image 1126.

The embodiments described herein provide a way to extend LPR from binary to tritone masks. In LPR, the accuracy of the lithography model significantly impacts the final recovered masks and their printability check. Therefore, the accuracy of the lithography model is crucial for final performance of defected mask recovery. It also faces challenges when a one level set is used to represent a tritone attPSM for lithography simulation. A single level set-based binary mask representation is no longer sufficient for tritone mask lithography modeling. Mask representation using two level sets and their movement during optimization demonstrate significantly valuable advantages for tritone LPR.

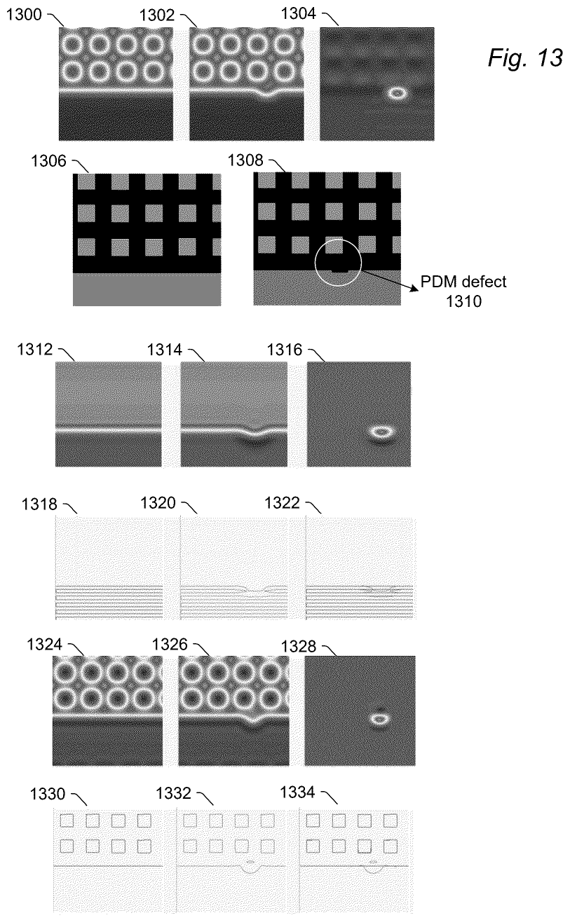

In the example shown in FIG. 13, one edge defect example is shown along a tritone layer (on a chrome layer) demonstrating how the one level-set based LPR performs poorly compared to the proposed two-level set based LPR approach. Inspection images (generated by a reticle inspection tool) including reference transmitted image 1300, test transmitted image 1302, and difference transmitted image 1304 are generated for a mask on which reference design patterns 1306 and defective design patterns 1308 are printed. Defective design patterns include programmed defect mask (PDM) defect 1310, which is the edge defect example along the tritone chrome layer.

Simulation images were generated using one level set binary mask representation for the tritone attPSM mask. The simulation images include simulated reference transmitted image 1312, simulated test transmitted image 1314, and simulated difference transmitted image 1316. Reference mask contour image 1318, test mask contour image 1320, and test/reference mask contour image 1322 were also generated. As shown by comparing the reference inspection and simulated images, the test inspection and simulated images, and the difference inspection and simulated images, the chrome layer merged to glass in the one level set binary mask representation which produces not good simulation results. As a result, the simulation results may cause a fake success design pattern lookup, incorrect reference mask from ADC design pattern lookup, and incorrect recovered test mask image.

In contrast, simulation images were generated using a two level set tritone mask representation for the tritone attPSM mask. The simulation images include simulated reference transmitted image 1324, simulated test transmitted image 1326, and simulated difference transmitted image 1328. Reference mask contour image 1330, test mask contour image 1332, and test/reference mask contour image 1334 were also generated. As shown by comparing the reference inspection and simulated images, the test inspection and simulated images, and the difference inspection and simulated images, the chrome layer on top of MoSi was correctly represented and the simulations match well. As a result, these simulation images may produce correct success design pattern lookup, correct reference mask image from ADC design pattern lookup, and a reasonable recovered test mask. Similar results were observed for other defect types like pinhole defects in the chrome layer.

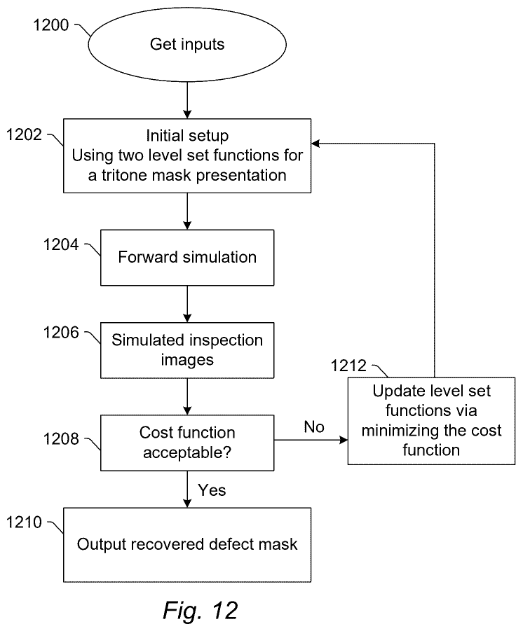

FIG. 12 provides more technical details on tritone LPR performed with a two level-set based tritone attPSM mask representation. In addition, FIG. 12 shows an embodiment of a workflow of inversion of a tritone attPSM mask. As shown in FIG. 12, step 1200 may include getting inputs, which may include any of the inputs described herein. Step 1200 may also include setting up the system-wide settings, preparing the runtime environments, and obtaining a set of initial inputs, including, but not limited to, the reference photomask design file and high-resolution inspection images for both the reference and defected masks.

Step 1202 includes initial setup using two level set functions for a tritone mask representation, which may be performed as shown in FIG. 9. Step 1202 may also process the input data files from step 1200 and initialize the mask inversion flow. From the original reference mask, this step provides the basic tones or level sets representation for an initial guess of the defected photomask.

In a further embodiment, determining the information includes performing photomask pattern recovery from one or more images of the photomask generated by a tool that performs a process on the photomask in combination with the determined tone as the function of the position on the photomask thereby generating a modeled representation of the photomask. Performing photomask pattern recovery in this manner may be performed in forward simulation step 1204. Forward simulation step 1204 uses the two-level-set representation of the tritone defective mask to perform a lithography simulation, outputting the simulated inspection images in step 1206. The forward simulation may be performed as described further herein (e.g., using one or more of mask fabrication process model 106 and mask inspection process model 108 shown in FIG. 1). The one or more images of the photomask generated by a tool that performs a process on the photomask may include, for example, one or more mask inspection images, including any of such images described herein.

In one such embodiment, results of determining the tone performed with the reference data include an initial guess for the tone of the photomask as the function of the position on the photomask, and performing the photomask pattern recovery includes generating a simulated image of the photomask based on the initial guess as input to a forward simulation of the process performed on the photomask to generate the one or more images of the photomask. For example, determining the tone may be performed as described herein (as shown in FIG. 9) to generate an initial guess for the tone of the photomask, and the initial guess may be input to the forward simulation to generate the one or more simulated images of the photomask. These steps may be performed as described further herein.

In another embodiment, performing the photomask pattern recovery includes comparing the simulated image to at least one of the one or more images of the photomask, determining a cost function value based on results of the comparing, and determining if the cost function value is acceptable. These steps may be performed in step 1208 of FIG. 12 shown simply in the figure as determining if the cost function is acceptable. Step 1208 uses the simulated inspection images 1206 to compute a cost function (H), which aims to minimize the differences between the recovered defected mask (simulated inspection image) and the real defected mask (real inspection image). The cost function may include any suitable cost function known in the art and may be computed in any suitable manner.

In a further embodiment, when the cost function value is determined to be not acceptable, performing the photomask pattern recovery includes modifying the initial guess thereby generating a new guess for the tone of the photomask as the function of the position on the photomask, generating an additional simulated image of the photomask based on the new guess as the input to the forward simulation, comparing the additional simulated image to the at least one of the one or more images of the photomask, determining an additional cost function value based on results of comparing the additional simulated image to the at least one of the one or more images of the photomask, and determining if the additional cost function value is acceptable. For example, if the cost function is not acceptable, the workflow may proceed to step 1212 in which the level set functions are updated via minimizing the cost function. In this manner, if the cost function value is not acceptable, the two-level-set representation is updated in step 1212 by minimizing the cost function. The updated two-level-set representation is then passed back to step 1202. Steps 1202, 1204, 1206, and 1208 may then be performed for the updated two-level-set representation in the same manner described herein.

In some embodiments, when the cost function value is determined to be acceptable, performing the photomask pattern recovery includes outputting the initial guess as the modeled representation of the photomask. In an additional embodiment, when the additional cost function value is determined to be acceptable, performing the photomask pattern recovery includes outputting the new guess as the modeled representation of the photomask. For example, if the modeled representation of the photomask generated with the initial guess for the tone of the photomask generates an acceptable cost function, that modeled representation may be output as the recovered defect mask in step 1210. If this is not the case, this cycle repeats from step 1202 until the cost function is determined to be acceptable in step 1208, at which point the recovered defect mask generated with the current guess for the tone of the photomask is output in step 1210.

LPR may be performed for any defects detected on the photomask, e.g., by mask inspection 116 shown in FIG. 1 and/or defect detection 1026 shown in FIG. 10. For example, in some embodiments, one or more defects are detected on the photomask in the one or more images. In one such embodiment, the one or more defects include defects on the photomask caused by photomask fabrication. In this manner, the new proposed mask inversion using a two level-set based tritone mask model may target hard defects from a tritone mask. “Hard defects” generally refer to issues such as missing or added absorbers, which typically occur in the mask shop during mask manufacturing. In contrast, “soft defects” generally include particles, contamination, or accumulated haze, which mostly occur in the fab. Although the embodiments described herein have shown to be particularly useful for hard defects, the multiple level-set approach embodiments described herein can be extended to inversion of soft defects on a tritone mask. For example, the embodiments described herein can be extended to the inversion of soft defects, such as contamination, on a tritone mask by further enhancing the multi-level-set approach.

In another embodiment, determining the information also includes determining printability of one or more defects on the photomask on a wafer patterned with the photomask, and determining the printability is performed based on at least the modeled representation of the photomask. In one such embodiment, determining the printability includes simulating the wafer patterned with the photomask. For example, the modeled representation of the photomask may be input to an additional simulation such as wafer fabrication process model 110 shown in FIG. 1. In particular, as described further herein, the wafer fabrication process model may generate simulated images of a wafer on which a mask is printed, and possibly for one or more parameter variations of the wafer fabrication process. In this manner, a representation of the fabricated mask may be used to generate simulated wafer images. The modeled representation of the mask, e.g., output recovered defect mask 1210 shown in FIG. 12, may be input to such a model to thereby generate simulated wafer images.

The simulated wafer images may then be analyzed to determine if a defect on the mask will print on the wafer, how well the patterns on the mask will print on the wafer, if the patterns printed on the wafer with the mask will be sufficiently similar to the design intent for the patterns, etc. For example, defect detection may be performed with the simulated wafer images to determine if the mask and/or a defect on the mask will produce a defect on the wafer. In a similar manner, metrology-like analysis of the simulated wafer images may be performed to determine how well the mask will print the patterns on the wafer. Such printability analysis may be further performed in any suitable manner known in the art. In other words, the modeled representation of the mask generated as described herein may be used in the same manner as any other mask representation to analyze printability of the mask.

The embodiments described herein can be used in applications in addition to those already described. For example, the embodiments described herein can use the same approach to generate defective masks. Another application is using the two-level-set-based approach to represent the extreme ultraviolet (EUV) mask black-border region. For example, if the multi-layer (ML) on an EUV mask is over-etched and the substrate (quartz) is exposed, which is referred to as the “BlackBorder” region, then this area may be treated by the embodiments described herein as a tritone layer in the same manner as described herein.

The embodiments described herein provide a number of improvements and advantages over previously used methods and systems due to the new features of the embodiments described herein. For example, for reticle inspection on tritone attPSM masks, a more accurate lithography simulator using a two level-set approach can lead to more successful outcomes in applications like ADC and LPR. These more successful outcomes are due to the more reliable and successful pattern lookup and topology markup of the embodiments described herein, ultimately significantly improving overall defect classification efficiency. Additionally, for LPR, the more accurate lithography modeling and efficient defective tritone mask recovery during merit function optimization contribute to better printability results.

All of the embodiments described herein may include storing results of one or more steps of the embodiments in a computer-readable storage medium. The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used by another software module, method, or system, etc.

As described herein, the embodiments may be configured for determining tone of a photomask as a function of position on the photomask, which may then be used for one or more applications such as ADC and/or LPR in mask inspection. However, the determined tone may be used in one or more other processes described herein such as selecting one or more parameters for wafer inspection based on the determined tone, selecting one or more parameters for mask defect review, repair, etc. based on the determined tone. The embodiments described herein may be configured for selecting such parameters, or the computer system may store the determined tone so that it can be used for selecting such parameters and/or for functions performed during those processes such as ADC during wafer inspection, determining characteristics of the reticle during mask metrology, etc. In this manner, the computer system may be configured for storing the determined tone and/or any parameters of any process determined based on the tone in a recipe for a process and/or so that the determined tone and/or process parameters can be accessed and used for performing a process.

The computer system may be configured for storing information for the determined tone, the selected process parameter(s), etc. for process setup and/or for use in any of the processes described herein. The computer system may be configured to store the information in a recipe or by generating a recipe for the process in which the selected parameter(s) will be used. A “recipe” as that term is used herein can be generally defined as a set of instructions that can be used by a tool to perform a process on a specimen. In this manner, generating a recipe may include generating information for how a process is to be performed, which can then be used to generate the instructions for performing that process. The information for the selected parameter(s) that is stored by the computer system may include any information that can be used to identify and/or use the selected parameter(s) (e.g., such as a file name and where it is stored, and the file may include information for the parameter(s) such as parameter names, parameter values, etc.).

The information for the selected parameter(s) and/or the recipe may then be used by the system or method (or another system or method) to perform one or more processes on the mask or wafer, e.g., mask or wafer inspection, to thereby generate information (e.g., defect information) for the mask and/or wafer, metrology information for the mask and/or wafer, defect review information for the mask and/or wafer, etc. The information generated by such processes may include, for example, results for any defects detected on the mask and/or wafer such as location, etc., of the bounding boxes of the detected defects, detection scores, information about defect classifications such as class labels or IDs, etc., measurements of patterns formed on the mask and/or wafer, or any such suitable information known in the art. The results for the defects and/or patterns may be generated by the computer system or any other tools described herein in any suitable manner. The results for the defects, measurements, defect review results, etc. may have any suitable form or format such as a standard file type. The computer system may generate and store the results such that the results can be used by the computer system and/or another system or method to perform one or more functions for the mask and/or wafer. For example, that information may be used by the computer system or another system or method for sampling the defects for defect review or other analysis, determining a root cause of the defects, etc.

Functions that can be performed using such information also include, but are not limited to, altering a process such as a fabrication process or step that was or will be performed on the mask, a wafer printed with the mask, or another specimen in a feedback or feedforward manner. For example, the computer system may be configured to determine one or more changes to a process that was performed on a mask and/or a process that will be performed on the mask. In one embodiment, the computer system is configured for altering one or more parameters of a process tool used to perform a process on the mask based on results of one or more steps described herein. The changes to the process may include any suitable changes to one or more parameters of the process. The computer system preferably determines those changes such that defects can be reduced or prevented on the mask, the defects can be corrected or eliminated on the mask in another process performed on the mask, the defects can be compensated for in another process performed on the mask, etc. The computer system may determine such changes in any suitable manner known in the art.

Those changes can then be sent to a semiconductor fabrication system (not shown) or a storage medium (not shown) accessible to the computer system and the semiconductor fabrication system. The semiconductor fabrication system may or may not be part of the system embodiments described herein. For example, the computer system may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a chemical-mechanical polishing (CMP) tool, a deposition tool, and the like.

Each of the embodiments of each of the systems described above may be combined together into one single embodiment.

Another embodiment relates to a computer-implemented method for determining information for a photomask. The method includes determining tone of a photomask as a function of position on the photomask by applying predefined rules to reference data for the photomask when multiple level sets of the photomask overlap. The photomask has three or more tones, and the multiple level sets include three or more definitions for the three or more tones, respectively. The method also includes determining information for the photomask from the determined tone as the function of the position on the photomask. These steps are performed by a computer system.

Each of the steps of the method may be performed as described further herein. The method may also include any other step(s) that can be performed by the system and/or computer subsystem(s) or system(s) described herein, which may be configured according to any of the embodiments described herein. In addition, the method described above may be performed by any of the system embodiments described herein.

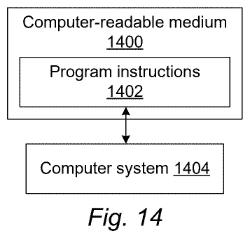

An additional embodiment relates to a non-transitory computer-readable medium storing program instructions executable on a computer system for performing a computer-implemented method for determining information for a photomask. One such embodiment is shown in FIG. 14. In particular, as shown in FIG. 14, non-transitory computer-readable medium 1400 includes program instructions 1402 executable on computer system 1404. The computer-implemented method may include any step(s) of any method(s) described herein.

Program instructions 1402 implementing methods such as those described herein may be stored on computer-readable medium 1400. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), SSE (Streaming SIMD Extension) or other technologies or methodologies, as desired.

Computer system 1404 may be configured according to any of the embodiments described herein.

Further modifications and alternative embodiments of various aspects of the invention will be apparent to those skilled in the art in view of this description. For example, methods and systems for determining information for a photomask are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A system configured for determining information for a photomask, comprising:
a computer system configured for:
determining tone of a photomask as a function of position on the photomask by applying predefined rules to reference data for the photomask when multiple level sets of the photomask overlap, wherein the photomask has three or more tones, and wherein the multiple level sets comprise three or more definitions for the three or more tones, respectively; and
determining information for the photomask from the determined tone as the function of the position on the photomask.

2. The system of claim 1, wherein determining the tone comprises identifying boundaries of the multiple level sets as the function of the position on the photomask thereby generating a numerical contour representation of the photomask, and wherein applying the predefined rules comprises determining zero contours of the predefined rules from the numerical contour representation.

3. The system of claim 1, wherein the computer system is further configured for storing the determined tone as the function of the position on the photomask as a two-level set-based representation of the photomask.

4. The system of claim 1, wherein determining the information comprises lithography modeling of the photomask based on the determined tone as the function of the position on the photomask.

5. The system of claim 4, wherein determining the information further comprises identifying design data for the photomask as the function of the position on the photomask based on results of the lithography modeling.

6. The system of claim 4, wherein determining the information further comprises identifying topology of the photomask as the function of the position on the photomask based on results of the lithography modeling.

7. The system of claim 6, wherein determining the information further comprises performing automatic defect classification of one or more defects detected on the photomask based on at least the identified topology.

8. The system of claim 1, wherein determining the information comprises performing photomask pattern recovery from one or more images of the photomask generated by a tool that performs a process on the photomask in combination with the determined tone as the function of the position on the photomask thereby generating a modeled representation of the photomask.

9. The system of claim 8, wherein results of determining the tone performed with the reference data comprise an initial guess for the tone of the photomask as the function of the position on the photomask, and wherein performing the photomask pattern recovery comprises generating a simulated image of the photomask based on the initial guess as input to a forward simulation of the process performed on the photomask to generate the one or more images of the photomask.

10. The system of claim 9, wherein performing the photomask pattern recovery further comprises comparing the simulated image to at least one of the one or more images of the photomask, determining a cost function value based on results of said comparing, and determining if the cost function value is acceptable.

11. The system of claim 10, wherein when the cost function value is determined to be acceptable, performing the photomask pattern recovery further comprises outputting the initial guess as the modeled representation of the photomask.

12. The system of claim 10, wherein when the cost function value is determined to be not acceptable, performing the photomask pattern recovery further comprises modifying the initial guess thereby generating a new guess for the tone of the photomask as the function of the position on the photomask, generating an additional simulated image of the photomask based on the new guess as the input to the forward simulation, comparing the additional simulated image to the at least one of the one or more images of the photomask, determining an additional cost function value based on results of comparing the additional simulated image to the at least one of the one or more images of the photomask, and determining if the additional cost function value is acceptable.

13. The system of claim 12, wherein when the additional cost function value is determined to be acceptable, performing the photomask pattern recovery further comprises outputting the new guess as the modeled representation of the photomask.

14. The system of claim 8, wherein one or more defects are detected on the photomask in the one or more images.

15. The system of claim 14, wherein the one or more defects comprise defects on the photomask caused by photomask fabrication.

16. The system of claim 8, wherein determining the information further comprises determining printability of one or more defects on the photomask on a wafer patterned with the photomask, and wherein determining the printability is performed based on at least the modeled representation of the photomask.

17. The system of claim 16, wherein determining the printability comprises simulating the wafer patterned with the photomask.

18. The system of claim 1, wherein the photomask is configured as a tri-tone attenuated phase-shift mask, and wherein the multiple level sets comprise two level sets.

19. A non-transitory computer-readable medium, storing program instructions executable on a computer system for performing a computer-implemented method for determining information for a photomask, wherein the computer-implemented method comprises:
determining tone of a photomask as a function of position on the photomask by applying predefined rules to reference data for the photomask when multiple level sets of the photomask overlap, wherein the photomask has three or more tones, and wherein the multiple level sets comprise three or more definitions for the three or more tones, respectively; and
determining information for the photomask from the determined tone as the function of the position on the photomask.

20. A computer-implemented method for determining information for a photomask, comprising:
determining tone of a photomask as a function of position on the photomask by applying predefined rules to reference data for the photomask when multiple level sets of the photomask overlap, wherein the photomask has three or more tones, and wherein the multiple level sets comprise three or more definitions for the three or more tones, respectively; and
determining information for the photomask from the determined tone as the function of the position on the photomask, wherein determining the tone and determining the information are performed by a computer system.
